(19) United States
(12) Patent Application Publication
(10) Pub. No.: US 2005/0184650 A1
(43) Pub. Date: Aug. 25, 2005

(54) [ORGANIC ELECTRO-LUMINESCENT DEVICE AND FABRICATING METHOD THEREOF]

(76) Inventors: Yu-Ren Peng, Hsinchu County (TW); Lai-Cheng Chen, Hsinchu (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 10/709,850

(22) Filed: Jun. 2, 2004

(30) Foreign Application Priority Data
Feb. 24, 2004 (TW) 93104548

(51) Int. Cl. H05B 33/00

(52) U.S. Cl. 313/503; 313/506

(57) ABSTRACT

An organic electro-luminescent device comprising a first substrate, a conductive layer and a second substrate is provided. A first electrode layer and an organic functional layer are sequentially laid on the first substrate. A second electrode is laid on the second substrate. The conductive layer is sandwiched between the second electrode layer and the organic functional layer. The second electrode layer is electrically connected to the organic functional layer through the conductive layer. Because the second electrode layer is disposed on the second substrate individually, one has no misgiving about damaging the other film layers during the fabrication of the second electrode layer. In other words, the organic electro-luminescent device has a wider processing window.

### CROSS REFERENCE TO RELATED APPLICATIONS

This application claims the priority benefit of Taiwan application Ser. No. 93104548, filed on Feb. 24, 2004.

### BACKGROUND OF INVENTION

1. Field of the Invention

The present invention relates to an organic electro-luminescent device. More particularly, the present invention relates to an organic electro-luminescent device with improved electrical properties and fabricating method thereof.

2. Description of the Related Art

To a large extent, the popularity of multimedia in our society is a result of the big leap in the technique in manufacturing semiconductor and display devices. In recent years, flat panel displays have been widely adopted as a mainstream display product because of its many special qualities including a high picture quality, optimal spatial utilization, low power consumption and radiation-free operation.

Many types of displays belong to flat panel displays. They include liquid crystal displays (LCD), organic electro-luminescent display (OELD) and plasma display panels (PDP). Organic electro-luminescent display is a type of self-emissive dot matrix display. Major characteristics of an OELD are: no viewing angle restrictions, low production cost, high responding speed (up to a hundred times that of the liquid crystals), low power consumption, DC low voltage driven, high operating temperature range, light weight and easily miniaturized and streamlined. Hence, OELD has the greatest potential to become the dominant type in the next generation of flat panel displays.

Typically, organic electro-luminescent display can be classified into bottom emission type and top emission type. The bottom emission type of OELD has a transparent anode, an organic material layer and a metallic cathode layer sequentially formed over a substrate. Although the light from the organic material layer emits in all possible direction, light heading towards the top will be reflected downward by the metallic cathode layer. Ultimately, most of the light will emerge from the bottom of the OELD after passing through the transparent anode layer. Conversely, if the cathode is fabricated from a transparent material while the anode is fabricated from a metal, any light from the organic material layer heading towards the bottom will be reflected upward by the metallic anode layer. Therefore, most of the light will emerge from the top of the OELD after passing through the transparent cathode layer. Furthermore, both the upper and the lower electrode layer can be fabricated using a transparent material so that light may emerge from both surface of the display. This type of OELD is often called a double-sided OELD.

In general, metal has a high electrical conductivity and hence is a suitable material for fabricating electrodes. Because the transparency of a metallic layer to visible light is low, thickness of the electrode must be precisely limited in the organic electro-luminescent display so that light can emerge from the electrode. Since electrical conductivity of the electrode is directly proportional to its thickness, reducing the thickness of the electrode will lead to a drop in its electrical conductivity.

To resolve the aforementioned issue, transparent conductive oxide (TCO) is used to form the conductive electrode of an organic electro-luminescent display. However, because of the strong bonding and high melting point properties of the TCO material, it is difficult to form a TCO film by performing a heat evaporation process. If a high-energy beam of electrons or a sputtering method is used to form a layer of TCO film, the interface between the TCO film and the organic material layer is likely to comprise some defects. Hence, the film must be deposited slowly leading to a long process time. Although the organic material layer can be protected by a buffer layer, the additional buffer layer may shift the electron-hole combination position from the emission layer and result in a drop in the light-emitting efficiency. If a laser evaporation method is deployed, the laser absorption properties of the material must be considered. Hence, a limit to the coating rate must be set.

Furthermore, forming a TCO material layer with a high electrical conductivity and a high transparency demands careful consideration of temperature as well as environmental factors. This is because highly conductive and transparent TCO material is grown only at a fairly high temperature accompanied by the provision of hydrogen or other reactive gases. Yet, at these processing conditions, some of the organic material layer underneath the electrode may disintegrate and the performance of the device may be affected.

### SUMMARY OF INVENTION

Accordingly, at least one objective of the present invention is to provide an organic electro-luminescent device whose anode and cathode are fabricated on a different substrate so that electrical conductivity and light transparency of the electrode is optimized and integrity of its underlying organic material layer is maintained.

At least a second objective of the present invention is to provide a method of fabricating an organic electro-luminescent device capable of forming an electrode with a high electrical conductivity and light transparency but without damaging other film layers so that light-emitting efficiency of the organic electro-luminescent device is improved.

To achieve these and other advantages and in accordance with the purpose of the invention, as embodied and broadly described herein, the invention provides an organic electro-luminescent device. The organic electro-luminescent device mainly comprises a first substrate, a conductive layer and a second substrate. The first substrate has a first electrode layer and an organic functional layer stacked thereon. The second substrate has a second electrode layer. The conductive layer is sandwiched between the second electrode layer and the organic functional layer. The second electrode is electrically connected to the organic functional layer through the conductive layer.

The present invention also provides a method of fabricating an organic electro-luminescent device. First, a first electrode layer is formed on a first substrate and then an organic function layer is formed over the first electrode layer. Thereafter, a second electrode layer is formed over a second substrate to prevent any damage to the organic function layer. Finally, the first substrate and the second substrate are attached together so that the second electrode layer and the organic functional layer are electrically connected.

According to the embodiment of the present invention, a low work function material layer is formed over the organic function layer so that the energy barrier for injecting carriers into the organic functional layer is lowered and the performance of the device is improved.

According to the embodiment of the present invention, the organic electro-luminescent device is an active light-emitting device. The first substrate is a substrate with an array of active devices such as thin film transistors connected through data lines and scan lines, for example. The first electrode layer over the first substrate is the pixel electrode of an active organic electro-luminescent device and the second electrode layer is a common electrode, for example.

According to the embodiment of the present invention, the organic electro-luminescent device is a passive light-emitting device, for example. The first electrode layer comprises a plurality of first stripe electrodes and the second electrode layer comprises a plurality of second stripe electrodes. The first stripe electrodes are parallel to each other. Similarly, the second stripe electrodes are parallel to each other. However, the first stripe electrodes extend in a direction different from the second stripe electrodes. Preferably, each first stripe electrode crosses over the second stripe electrodes perpendicularly such that each overlapping area forms a rectangular light-emitting region.

According to the embodiment of the present invention, the conductive layer is an anisotropic conductive film (ACF) or other types of film capable of electrically connecting the second electrode layer to the organic functional layer.

According to the embodiment of the present invention, the first electrode layer and the second electrode layer are fabricated using a transparent conductive material comprising, for example, indium tin oxide, indium zinc oxide, aluminum zinc oxide, antimony tin oxide, zinc oxide, indium oxide and tin oxide.

According to the embodiment of the present invention, the method of attaching the first substrate and the substrate together comprises forming a conductive layer between the second electrode layer and the organic functional layer. Thereafter, the second electrode layer and the conductive layer are press-bonded together so that the second electrode layer is electrically connected to the organic functional layer through the conductive layer.

According to the embodiment of the present invention, the method of forming the second conductive layer comprises performing a chemical vapor deposition process or a physical vapor deposition process. Furthermore, the organic functional layer comprises a low molecular weight compound and a high molecular weight compound material layer. The method of forming the low molecular weight compound material layer comprises evaporation, plasma polymerization, dip coating or spin coating. The method of forming the high molecular weight compound material layer comprises ink jet processing, dip coating, and spin coating.

In the present invention, the electrodes of the organic electro-luminescent device are formed on two separate substrates so that the electrode fabrication process is no longer limited by the need to prevent any damage to underlying film layers. Therefore, an electrode layer with better electrical properties is produced. Ultimately, the light-emitting efficiency of the organic electro-luminescent device will improve.

It is to be understood that both the foregoing general description and the following detailed description are exemplary, and are intended to provide further explanation of the invention as claimed.

### BRIEF DESCRIPTION OF DRAWINGS

The accompanying drawings are included to provide a further understanding of the invention, and are incorporated in and constitute a part of this specification. The drawings illustrate embodiments of the invention and, together with the description, serve to explain the principles of the invention.

FIGS. 1A through 1C are schematic cross-sectional views showing the steps for fabricating an organic electro-luminescent device according to one preferred embodiment of the present invention.

FIGS. 2A through 2C are schematic cross-sectional views showing a series of partially finished organic electro-luminescent devices according to the present invention.

FIG. 3 is an explosive view of a portion of an active organic electro-luminescent device served as an example of the organic electro-luminescent device in FIG. 1C.

FIG. 4 is an explosive view of a portion of a passive organic electro-luminescent device served as an example of the organic electro-luminescent device in FIG. 1C.

### DETAILED DESCRIPTION

Reference will now be made in detail to the present preferred embodiments of the invention, examples of which are illustrated in the accompanying drawings. Wherever possible, the same reference numbers are used in the drawings and the description to refer to the same or like parts.

In the present invention, the two electrodes of an organic electro-luminescent device are formed on different substrates to prevent damage to other film layer during fabrication. In the following, an embodiment of the present invention is used to illustrate the organic electro-luminescent device and fabricating method thereof. However, the scope of the present invention should not be limited as such.

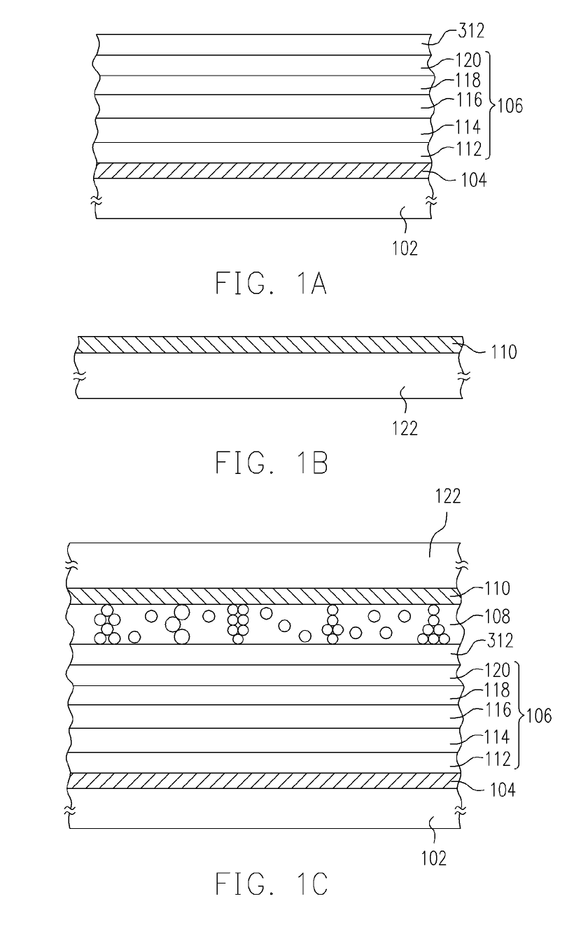

FIGS. 1A through 1C are schematic cross-sectional views showing the steps for fabricating an organic electro-luminescent device according to one preferred embodiment of the present invention. As shown in FIG. 1A, a first electrode layer 104 and an organic functional layer 106 are sequentially formed over a substrate 102. The first electrode layer 104 is formed, for example, by performing a chemical vapor deposition (CVD) process or a physical vapor deposition (PVD) process such as thermal evaporation, electron beam coating or sputtering. In the present embodiment, a low work function material layer 312 may also be formed over the organic functional layer 106 to lower the energy barrier for the injection of carriers into the organic functional layer 106 and improve device performance. The low work function material layer 312 is fabricated using a material comprising calcium (Ca), magnesium/silver alloy (Mg:Ag), aluminum/lithium alloy (Al: Li) or lithium fluoride/aluminum composite metal in a physical vapor deposition process, for example.

In particular, the first electrode layer 104 can be fabricated using a metallic material or a transparent conductive material, depending on whether the organic electro-luminescent device is a bottom emission or a top emission type. The so-called transparent conductive material comprises indium tin oxide, indium zinc oxide, aluminum zinc oxide, antimony tin oxide, zinc oxide, indium oxide or tin oxide. Furthermore, because the transparent conductive material has a high melting point and a strong bonding strength, the first electrode layer 104 can be constructed by depositing the transparent conductive material over the first substrate 102 in an electron beam coating, sputtering or high-temperature film production process without damaging other film layer. After the deposition process, the transparent conductive layer can be annealed at a high temperature to improve the electrical properties of the first electrode layer 104.

The organic function layer 106 is formed, for example, by performing a vacuum or thermal evaporation, a spin coating or other deposition process. One skilled artisan may select an appropriate deposition according to the material chosen. For example, if the organic function layer 106 is fabricated using a low molecular weight compound, the method of choice is dry vacuum evaporation or wet dip coating and wet spin coating. Conversely, if the organic functional layer 106 is fabricated using a high molecular weight compound, the method of choice is dip coating, spin coating or other type of coating.

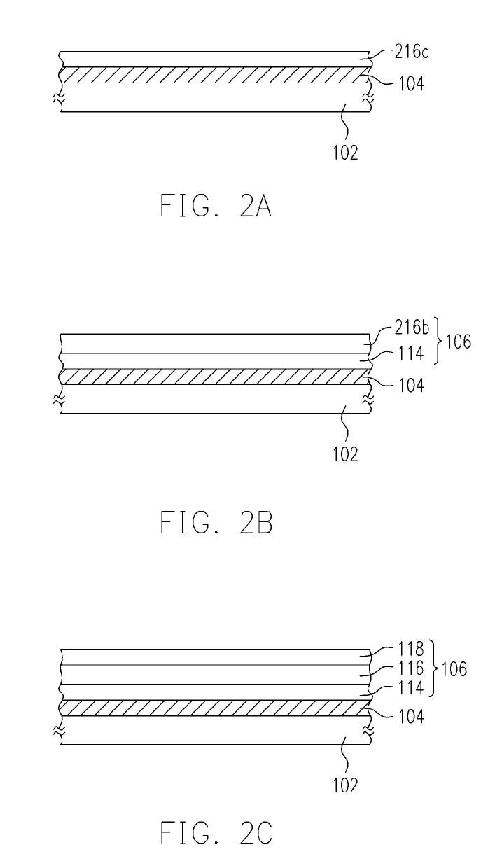

In the present embodiment, the first electrode layer 104 is an anode layer and the organic functional layer 106 is a composite stack on top of the first electrode layer comprising, from bottom to top, a hole injecting layer (HIL) 112, a hole transporting layer (HTL) 114, a emission layer (EL) 116, an electron transporting layer (ETL) 118 and an electron injecting layer (EIL) 120. However, in another embodiment of the present invention, the organic functional layer 106 can also be a single layer (a bipolar emission layer 216a as shown in FIG. 2A), a double layer (comprising an hole transporting layer 114 and an electron transporting emission layer 216b as shown in FIG. 2B) or a triple layer (comprising a hole transporting layer 114, an emission layer 116 and an electron transporting layer 118 as shown in FIG. 2C). One skilled artisan may notice that the number of stack layers in the organic functional layer 106 is mainly determined by the energy level distribution of the various material layers. Hence, no particular limit is set on the number of stack layers to be used in the organic function layer 106 in the present invention. In general, the number of stack layers depends on the design of the actual device.

As shown in FIG. 1B, a second electrode layer 110 is formed over a second substrate 122. In this embodiment, the second electrode layer 110 is a cathode layer, for example. Obviously, like the first electrode layer 104 in FIG. 1A, the second electrode layer 110 can also be fabricated using a metallic material or a transparent conductive material. Since the second electrode layer 110 is separately formed over the second substrate 122, a high-energy process can be used to form the second electrode layer 110 without affecting the organic functional layer 106. Therefore, the second electrode layer 110 can be fabricated using a method similar or identical to the one used to fabricate the first electrode layer 104. In other words, an electron beam coating or sputtering process can be used to form the second electrode layer 110 on the second substrate 122. Because a high-energy deposition process produces a film quickly, processing time for the second electrode layer 110 is shortened considerably. In addition, the quality of the organic functional layer no longer constitutes a constraint in the fabrication of the second electrode layer 110. Consequently, the second electrode layer 110 can have a wider processing window for improving the yield.

As shown in FIG. 1C, the first substrate 102 and the second substrate 122 are adhered together so that the second electrode layer 110 and the organic functional layer 106 are electrically connected. The method of adhering the first substrate 102 and the second substrate 122 together comprises providing a conducive layer 108 between the second electrode layer 110 and the organic functional layer 106. Thereafter, the first substrate 102 and the second substrate 122 are squeezed together at a constant and appropriate pressure and temperature. Here, the conductive layer 108 refers to any type of film material capable of electrically connecting the second electrode layer 110 and the organic functional layer 106 together. To stabilize the electrical connection between the second electrode layer 110 and the organic functional layer 106, an anisotropic conductive film (ACF) or functionally similar film can be chosen as the conductive layer 108. In general, the anisotropic conductive film contains a large number of conductive particles 130. When the second substrate 122 and the first substrate 102 are adhered together, the conductive particles 130 inside the conductive layer 108 contact the second electrode layer 110 directly and the organic functional layer 106 indirectly through the low work function material layer 312. In other words, the conductive layer 108 serves as a conductive medium between the second electrode layer 110 and the organic functional layer 106. Hence, an organic electro-luminescent device 100 is produced.

Thus, according to the aforementioned fabrication process, an organic electro-luminescent device 100 as shown in FIG. 1C is produced. In the following, the structure of the organic electro-luminescent device 100 is disclosed in detail.

As shown in FIG. 1C, the organic electro-luminescent device 100 of the present invention mainly comprises a first substrate 102, a conductive layer 108 and a second substrate 122. A first electrode layer 104, an organic functional layer 106 and a low work function material layer 312 are sequentially stacked over the first substrate 102. A second electrode layer 110 is disposed over the second substrate 122. The conductive layer 108 is sandwiched between the second electrode layer 110 and the organic functional layer 106 so that the second electrode layer 110 and the organic functional layer 106 are electrically connected by means of the conductive layer 108. A low work function material layer 312 is formed over the organic function layer so that the energy barrier for injecting carriers into the organic functional layer is lowered and the performance of the device is improved. The conductive layer 108 is an anisotropic conductive film (ACF), for example.

Furthermore, the types of materials that are used to fabricate the first electrode layer 104 and the second electrode layer 110 are largely determined by the emission type of the organic electro-luminescent device. For example, if the organic electro-luminescent device is a top emission type, a metallic material is used to form the first electrode layer 104 while a transparent conductive material is used to form the second electrode layer 110. With this setup, light from the organic functional layer 106 is reflected by the first electrode layer 104 to the top. Hence, all light rays emerge from the second substrate 122. The so-called transparent conductive material comprises, for example, indium tin oxide, indium zinc oxide, aluminum zinc oxide, antimony tin oxide, zinc oxide, indium oxide and tin oxide. On the other hand, if the organic electro-luminescent device is a bottom emission type, a transparent conductive material is used to form the first electrode layer 104 while a metallic material is used to form the second electrode layer 110. With this setup, light from the organic functional layer 106 is reflected by the second electrode layer 110 to the bottom. Hence, all light rays emerge from the first substrate 102. Aside from the aforementioned top and bottom emission type, transparent conductive material can be used to fabricate both the first electrode 104 and the second electrode 110 so that a double-sided organic electro-luminescent device is produced.

It should be noted that the organic electro-luminescent device 100 can be an active or a passive organic electro-luminescent device. In the following, active and passive organic electro-luminescent devices are described. Since the material and method of fabricating the first electrode layer, the second electrode layer, the organic functional layer, the conductive layer and the low function work material layer have been described in the aforementioned embodiment, details are not repeated here.

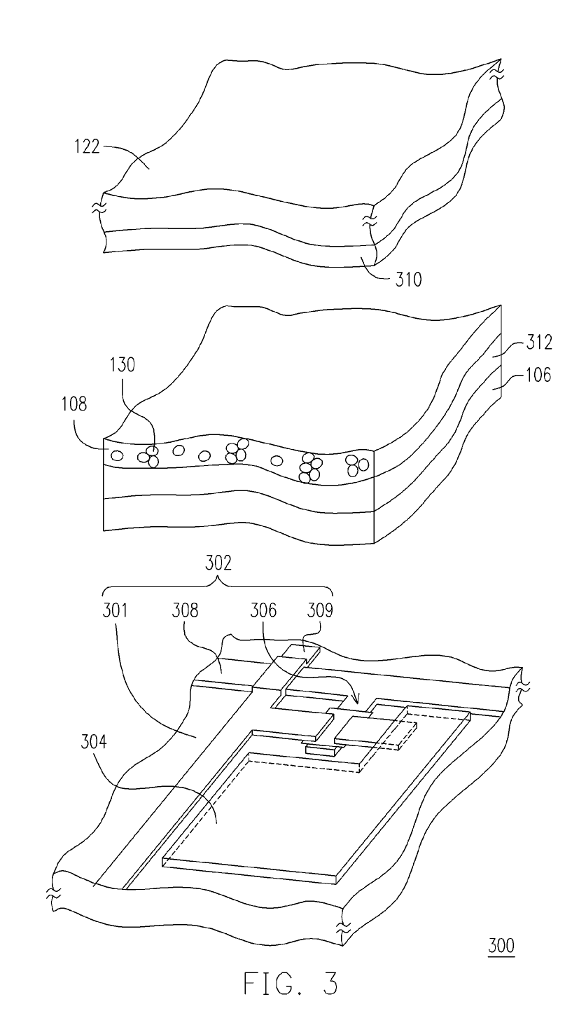

FIG. 3 is an explosive view of a portion of an active organic electro-luminescent device served as an example of the organic electro-luminescent device in FIG. 1C. The active organic electro-luminescent device 300 in FIG. 3 mainly comprises a first substrate 302, a second substrate 122 and a conductive layer 108. The first substrate 302 is a substrate with an array of active devices thereon. For example, the first substrate 302 can be a thin film transistor array substrate comprising a substrate 301, a plurality of thin film transistors 306, a plurality of scan lines 308 and a plurality of data lines 309. In general, the first electrode layer 304 is an anode disposed over the substrate 301 as a pixel electrode. The low work function material layer 312 is disposed over the organic functional layer 106 to lower the energy barrier for injecting carriers into the organic functional layer 106 and hence improve device performance.

It should be noted that the thin film transistor 306 of the present invention can be classified into amorphous silicon thin film transistor and low temperature polysilicon thin film transistor according to the material constituting the channel layer (not shown). In addition, the thin film transistor 306 can be classified into a top-gate thin film transistor and a bottom-gate thin film transistor according to the relative position between the channel layer and the gate. There is no set limit on the type of transistor to be used in active organic electro-luminescent device. It is within the scope of the present invention as long as the anode and the cathode of the active organic electro-luminescent device are formed on two separate substrates.

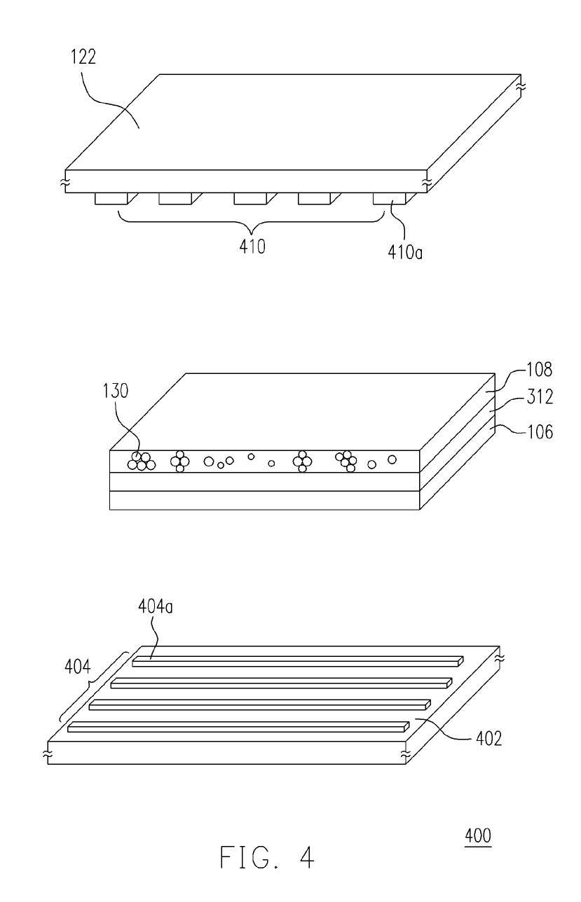

FIG. 4 is an explosive view of a portion of a passive organic electro-luminescent device served as an example of the organic electro-luminescent device in FIG. 1C. The passive organic electro-luminescent device 400 in FIG. 4 comprises a first substrate 402, a second substrate 122 and a conductive layer 108. A first electrode layer 404, an organic functional layer 106 and a low work function material layer 312 are sequentially stacked over the first substrate 402. A second electrode layer 410 is disposed over the second substrate 122. The first electrode layer 404 comprises a plurality of first stripe electrodes 404a and the second electrode layer 410 comprises a plurality of second stripe electrodes 410a. The first stripe electrodes 404a are parallel to each other. Similarly, the second stripe electrodes 410a are parallel to each other. However, the first stripe electrodes 404a extend in a direction different from the second stripe electrodes 410a. Preferably, each first stripe electrode layer 404 crosses over the second stripe electrodes 410 perpendicularly such that each overlapping area forms a rectangular light-emitting region.

In the present invention, the electrodes of the organic electro-luminescent device are formed on two separate substrates so that the electrode fabrication process is not limited by the need to prevent any damage to underlying film layers. Therefore, the processing window of the organic electro-luminescent device is increased because the processing conditions are no longer constrained by the quality of the organic functional layer. For example, a high-energy or plasma coating process can be used to form the electrodes using transparent conductive material in a shorter time. Moreover, a high-temperature film production process and high-temperature annealing can be carried out to improve the electrical properties and light transparency of the electrode.

In summary, the method of fabricating the organic electro-luminescent device according to the device prevents any damage to the organic functional layer and hence increases productivity. Furthermore, the method produces electrodes with better electrical properties and light transparency. Ultimately, the efficiency of light emission from the organic electro-luminescent device will improve.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

1. An organic electro-luminescent device, comprising:
a first substrate having a first electrode layer and an organic functional layer sequentially disposed thereon;
a second substrate having a second electrode layer disposed thereon; and
a conductive layer disposed between the organic functional layer and the second electrode layer, wherein the second electrode layer is electrically connected to the organic functional layer through the conductive layer.

2. The organic electro-luminescent device of claim 1, wherein the first substrate is a substrate with an array of active devices thereon, the first electrode layer comprises a plurality of pixel electrodes and the second electrode layer serves as a common electrode.

3. The organic electro-luminescent device of claim 1, wherein the first electrode layer comprises a plurality of parallel-aligned first stripe electrodes and the second electrode layer comprises a plurality of parallel-aligned second stripe electrodes such that the first stripe electrodes extend in a direction perpendicular to the second stripe electrodes.

4. The organic electro-luminescent device of claim 1, wherein the conductive layer comprises an anisotropic conductive film.

5. The organic electro-luminescent device of claim 1, wherein the first electrode layer comprises transparent conductive material.

6. The organic electro-luminescent device of claim 5, wherein the transparent conductive material is indium tin oxide, indium zinc oxide, aluminum zinc oxide, antimony tin oxide, zinc oxide, indium oxide or tin oxide.

7. The organic electro-luminescent device of claim 1, wherein the second electrode layer comprises transparent conductive material.

8. The organic electro-luminescent device of claim 7, wherein the transparent conductive material is indium tin oxide, indium zinc oxide, aluminum zinc oxide, antimony tin oxide, zinc oxide, indium oxide or tin oxide.

9. The organic electro-luminescent device of claim 1, wherein the device further comprises a low work function material layer disposed over the organic functional layer.

10. The organic electro-luminescent device of claim 1, wherein the material layer is calcium, magnesium-silver alloy, aluminum-lithium alloy or lithium fluoride/aluminum composite metal.

11. A method of fabricating an organic electro-luminescent device, comprising the steps of:
providing a first substrate;
forming a first electrode layer and an organic function layer in sequence over the first substrate;
providing a second substrate;
forming a second electrode layer over the second substrate; and
adhering the second substrate and the first substrate together so that the second electrode layer is electrically connected to the organic functional layer.

12. The method of claim 11, wherein the step of adhering the first substrate and the second substrate together comprises:
providing a conductive layer between the second electrode layer and the organic functional layer; and
electrically connecting the second electrode layer and the organic functional layer through the conductive layer.

13. The method of claim 11, wherein the step of forming the second electrode layer over the substrate comprises performing a chemical vapor deposition process or a physical vapor deposition process.

14. The method of claim 11, wherein the organic functional layer comprises a high molecular weight compound material.

15. The method of claim 14, wherein the step of forming the high molecular weight compound material comprises dip coating, ink jet or spin coating.

16. The method of claim 11, wherein the organic functional layer comprises a low molecular weight compound material.

17. The method of claim 16, wherein the step of forming the low molecular weight compound material comprises evaporation, plasma polymerization, dip coating or spin coating.

18. The method of claim 11, wherein after forming a first electrode layer and an organic function layer in sequence over the first substrate, further comprises forming a low work function material layer over the organic functional layer.
